(19) United States
(12) Patent Application Publication
(10) Pub. No.: US 2012/0235191 A1
(43) Pub. Date: Sep. 20, 2012

(54) SEMICONDUCTOR LIGHT EMITTING DEVICE AND PHOTOCOUPLER

(75) Inventors: Miwa ISHIDA, Fukuoka-ken (JP); Kenji Fujimoto, Fukuoka-ken (JP)

(73) Assignee: Kabushiki Kaisha Toshiba, Tokyo (JP)

(21) Appl. No.: 13/235,300

(22) Filed: Sep. 16, 2011

(30) Foreign Application Priority Data
Mar. 18, 2011 (JP) 2011-060939

(51) Int. Cl. H01L 33/60

(52) U.S. Cl. 257/98; 257/E33.072

(57) ABSTRACT

According to one embodiment, a semiconductor light emitting device includes a light emitting layer, a first layer, a second layer and a distributed Bragg reflector. The light emitting layer has a first and second surfaces and is capable of emitting emission light having a peak wavelength in a range of 740 nm or more and 830 nm or less. The first layer is provided on a side of the first surface and has a light extraction surface. The second layer is provided on a side of the second surface. The distributed Bragg reflector layer is provided on a side of the second layer. A third and fourth layers are alternately stacked. The distributed Bragg reflector layer is capable of reflecting the emission light toward the light extraction surface. The third and fourth layers each have a bandgap wavelength shorter than the peak wavelength.

### CROSS-REFERENCE TO RELATED APPLICATIONS

This application is based upon and claims the benefit of priority from the prior Japanese Patent Application No. 2011-060939, filed on Mar. 18, 2011; the entire contents of which are incorporated herein by reference.

### FIELD

Embodiments described herein relate generally to a semiconductor light emitting device and a photocoupler.

### BACKGROUND

In remote controls for electronic equipment and photocouplers for transmitting input/output signals with electrical insulation, near infrared light in the wavelength range of 0.74-1 μm is widely used.

An LED (light emitting diode) capable of emitting near infrared light can be used as a light emitting device. A Si photodiode can be used as a light receiving device. Then, near infrared light can be detected with good sensitivity.

It is preferable that the emission spectrum intensity be low outside the desired wavelength range for the light emitting device. For instance, in the case where the desired wavelength range is 740-830 nm, the light emitting device emits excitation light near 870 nm, which diffuses carriers generated in a deep region of the light receiving device. Thus, the light receiving device undergoes e.g. the tailing phenomenon at the falling edge of the pulse signal. This causes the problem of characteristics degradation such as pulse width distortion and signal delay in photocouplers.

### BRIEF DESCRIPTION OF THE DRAWINGS

FIG. 1A is a schematic sectional view of a semiconductor light emitting device according to a first embodiment, and FIG. 1B is a partially enlarged schematic sectional view of region D;

FIG. 2A is a graph of the emission spectrum of the semiconductor light emitting device according to the first embodiment, and FIG. 2B is a graph of the emission spectrum of a semiconductor light emitting device according to its variation;

FIG. 3 is a graph showing the dependence of the bandgap wavelength on the Al composition ratio of AlₓGa₁₋ₓAs (0≦x<0.45);

FIG. 4 is a graph showing luminosity curve;

FIG. 5 is a graph showing the range of the bandgap wavelength of the third layer and the fourth layers in the semiconductor light emitting device according to the first embodiment;

FIG. 6A is a graph showing the driving current waveform of the semiconductor light emitting device according to the first embodiment and the output current waveform converted from its emission light, and FIG. 6B is a graph showing the driving current waveform of the semiconductor light emitting device according to the variation of the first embodiment and the output current waveform converted from its emission light;

FIG. 7A is a graph showing the emission spectrum of a semiconductor light emitting device according to a comparative example, and FIG. 7B shows an output current waveform by the light receiving device;

FIG. 8A is a schematic view describing diffusion carriers generated in the light receiving device, and FIGS. 8B and 8C are schematic views describing the action by wavelength components longer than 830 nm, and FIGS. 8D and 8E are schematic views describing the action by wavelength components of 830 nm or less;

FIG. 9 is a graph showing the relative sensitivity of a Si photodiode;

FIG. 10A is a graph of the emission spectrum of the semiconductor light emitting device according to the second embodiment, and FIG. 10B is a graph showing the current waveform converted from its emission light; and

FIG. 11A is a schematic sectional view of a photocoupler according to this embodiment, and FIG. 11B is a schematic view showing the connection of terminals.

### DETAILED DESCRIPTION

In general, according to one embodiment, a semiconductor light emitting device includes a light emitting layer, a first layer of a first conductivity type, a second layer of a second conductivity type and a distributed Bragg reflector. The light emitting layer has a first surface and a second surface provided on an opposite side of the first surface. The light emitting layer is capable of emitting emission light having a peak wavelength in a wavelength range of 740 nm or more and 830 nm or less. The first layer is provided on a side of the first surface of the light emitting layer and has a light extraction surface provided on an opposite side of the light emitting layer. The second layer is provided on a side of the second surface of the light emitting layer. The distributed Bragg reflector layer is provided on a side of the second layer opposite to the light emitting layer and has the second conductivity type. A third layer and a fourth layer with a higher refractive index than the third layer are alternately stacked in the distributed Bragg reflector layer. The distributed Bragg reflector layer is capable of reflecting the emission light toward the light extraction surface. The third and fourth layers each have a bandgap wavelength shorter than the peak wavelength.

Various embodiments will be described hereinafter with reference to the accompanying drawings.

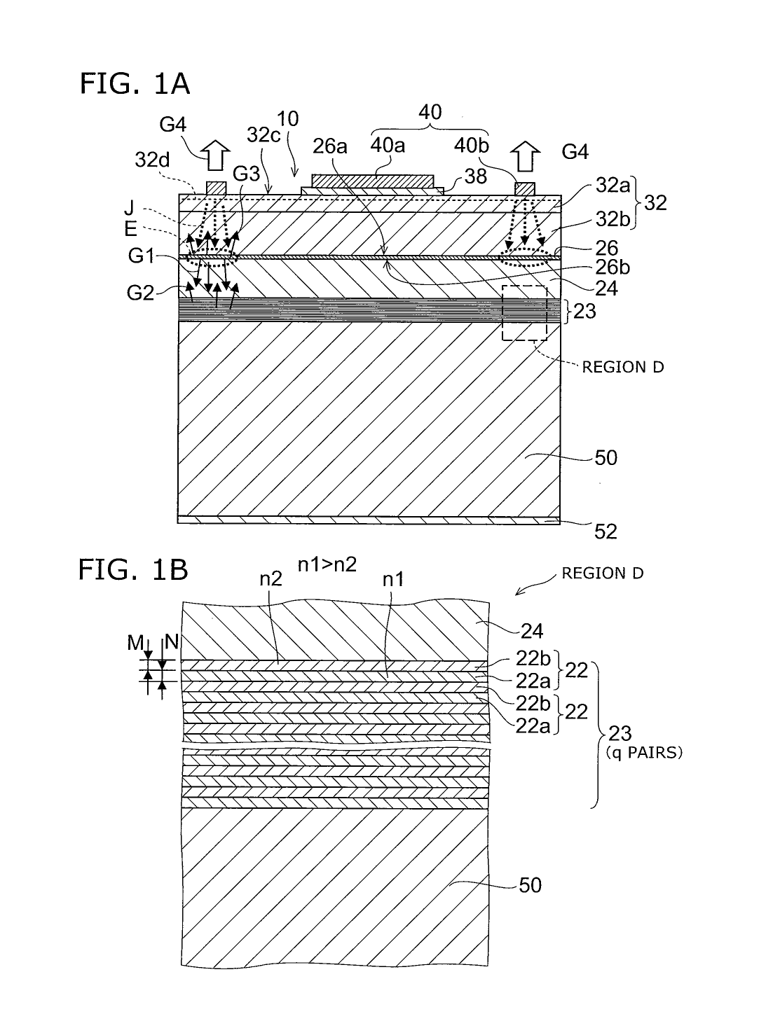

FIG. 1A is a schematic sectional view of a semiconductor light emitting device according to a first embodiment. FIG. 1B is a partially enlarged schematic sectional view of region D.

The semiconductor light emitting device 10 includes a light emitting layer 26, a first layer 32, a second layer 24, and a distributed Bragg reflector (DBR) layer 23.

The light emitting layer 26 has a first surface 26a and a second surface 26b on an opposite side of the first surface 26a. The light emitting layer 26 can emit emission light having a peak wavelength in the wavelength range of 740 nm or more and 830 nm or less. The first layer 32 is provided on a side of the first surface 26a of the light emitting layer 26, includes a light extraction surface 32c, and has a first conductivity type. The second layer 24 is provided on a side of the second surface 26b of the light emitting layer 26 and has a second conductivity type. The DBR layer 23 is provided on the side of the second layer 24 opposite to the light emitting layer 26 and has the second conductivity type. In the DBR layer 23, a third layer 22a and a fourth layer 22b are alternately stacked. The refractive index n2 of the fourth layer 22b is higher than the refractive index n1 of the third layer 22a. The DBR layer 23 can reflect the emission light toward the light extraction surface 32c.

In FIG. 1A, the semiconductor light emitting device 10 further includes a current blocking layer 38 provided above the light extraction surface 32c, a first electrode 40 provided above the current blocking layer 38, a substrate 50 provided below the DBR layer 23, and a second electrode 52 provided on the rear surface of the substrate 50.

The first electrode 40 may include a pad portion 40a and a thin wire portion 40b. In this case, the current blocking layer 38 provided between the pad portion 40a and the first layer 32 can reduce injection of carriers J into the region below the pad portion 40a. This can suppress light emission in the region below the pad portion 40a and increase the light extraction efficiency.

The first layer 32 may include a current spreading layer 32a provided on the thin wire portion 40b side and a cladding layer 32b provided on the light emitting layer 26 side. In the case where the current blocking layer 38 is provided between the first electrode 40a and the current spreading layer 32a, carriers J are injected from the thin wire portion 40b into the current spreading layer 32a and flow into the light emitting layer 26. That is, the neighborhood of region E of the light emitting layer 26 below the thin wire portion 40b constitutes a light emitting region E.

The light emitting layer 26, the first layer 32, the second layer 24, and the DBR layer 23 can include e.g. an InAlGaP-based material represented by the composition formula Inₓ(Al_{y}Ga_{1-y})₁₋ₓP (0≦x≦1, 0≦y≦1) or an AlGaAs-based material made of AlₓGa₁₋ₓAs (0≦x≦1). These materials may include elements serving as acceptors or donors.

The semiconductor light emitting device 10 according to the first embodiment emits near infrared light used for photocouplers and optical sensors. As described later, its wavelength range is preferably 740 nm or more and 830 nm or less.

In the first embodiment, the following materials are used, but the invention is not limited thereto. The substrate 50 is made of GaAs. The first layer 32 is made of e.g. an AlGaAs-based material or InAlGaP-based material. The light emitting layer 26 is made of e.g. AlₓGa₁₋ₓAs (0≦x<0.45) or InₓGa₁₋ₓAs (0≦x≦1). The second layer 24 is made of e.g. an AlGaAs-based material or InAlGaP-based material. The third layer 22a of the DBR layer 23 is made of an InₓAl₁₋ₓP-based material (0≦x≦1), and the fourth layer 22b of the DBR layer 23 is made of an AlGaAs-based material.

The light emitting layer 26 can be made of an MQW (multi-quantum well) structure, and the composition and structure of the MQW can be varied. This facilitates controlling the peak wavelength λp to within the wavelength range of 740 nm or more and 830 nm or less. Here, the peak wavelength λp refers to the wavelength maximizing the spectrum intensity in the emission spectrum with spreading.

In the case where emission light G1 emitted downward from the light emitting layer 26 passes one pair 22 of the fourth layer 22b and the third layer 22a, its optical path length can be set to half the peak wavelength λp. Then, the reflected light G2 can be enhanced by interference of light. Furthermore, with the increase in the number of pairs of the third layer 22a and the fourth layer 22b, the reflected light is further enhanced, and the reflectance can be further increased. In this case, the wavelength maximizing the reflectance of the DBR layer 23 can be substantially made equal to the peak wavelength λp of the emission light. Then, the emission light can be efficiently extracted outside from the light extraction surface 32c. Here, the number of pairs q can be suitably selected in the range of e.g. 10-30.

The third layer 22a and the fourth layer 22b can each be set to a quarter of the in-medium wavelength. This facilitates obtaining a high reflectance by a simple structure. In this case, the thickness M of the fourth layer 22b can be set to a quarter of the in-medium wavelength in the fourth layer (refractive index n2) 22b as given by equation (1):

M=(λ1/n2)/4 (1)

where λ1 is the free space wavelength of the emission light.

The thickness N of the third layer 22a can be set to a quarter of the in-medium wavelength in the third layer (refractive index n1) 22a as given by equation (2):

N=(λ1/n1)/4 (2)

The reflected light G2 by the DBR layer 23 and light G3 emitted upward from the light emitting layer 26 are extracted outside as emission light G4 from the light extraction surface 32c.

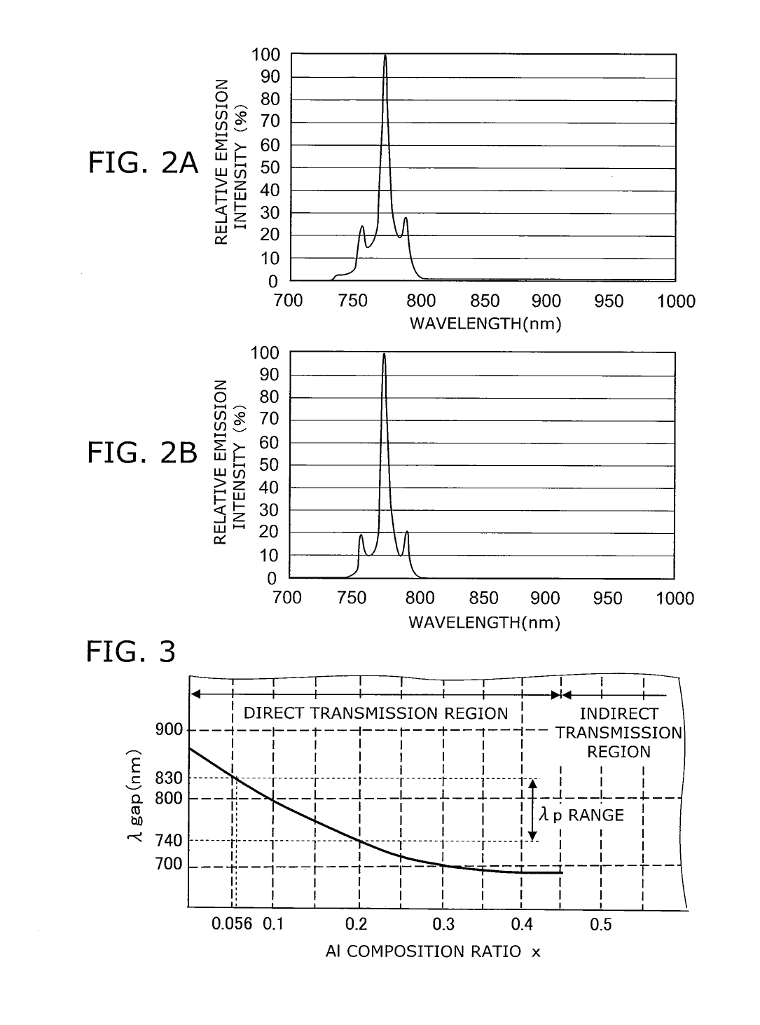

FIG. 2A is a graph of the emission spectrum of the semiconductor light emitting device according to the first embodiment. FIG. 2B is a graph of the emission spectrum of a semiconductor light emitting device according to its variation.

The semiconductor light emitting device according to the first embodiment of FIG. 2A includes 10 pairs of the third layer 22a made of In_{0.5}Al_{0.5}P and having the thickness N of equation (2) and the fourth layer 22b made of Al_{0.144}Ga_{0.856}As and having the thickness M of equation (1). The peak wavelength λp of the emission light is approximately 776 nm. Then, the refractive index n2 of the fourth layer 22b can be made higher than the refractive index n1 of the third layer 22a. Thus, the reflectance of the DBR layer 23 can be increased.

The fourth layer 22b made of Al_{0.144}Ga_{0.856}As exhibits direct transition in the wavelength range of 740-830 nm. Its bandgap wavelength λg4 is approximately 775 nm. That is, if the Al composition ratio x is set to 0.144 or more, the bandgap wavelength λg4 can be set to 775 nm or less. This can suppress that the fourth layer 22b emits light having a longer wavelength than the emission light having a peak wavelength λp of 776 nm. Furthermore, in the emission spectrum of the emission light, light components spread on the short wavelength side of the bandgap wavelength λg4 of the fourth layer 22b are absorbed by the fourth layer 22b. Thus, the external emission thereof can be suppressed.

Here, the bandgap wavelength λgap can be given by equation (3):

λAgap (nm)=1240/Eg (eV) (3)

where Eg is the bandgap energy.

The third layer 22a made of In_{0.5}Al_{0.5}P exhibits indirect transition. Thus, its emission light is suppressed. Here, the bandgap wavelength is approximately 528 nm.

The semiconductor light emitting device according to the variation of FIG. 2B includes 20 pairs of the third layer 22a made of In_{0.5}Al_{0.5}P and having the thickness N of equation (2) and the fourth layer 22b made of Al_{0.2}Ga_{0.8}As and having the thickness M of equation (1). The peak wavelength λp is approximately 776 nm. The fourth layer 22b made of Al_{0.2}Ga_{0.8}As exhibits direct transition in the wavelength range of 740-830 nm. Its bandgap wavelength λg4 is approximately 740 nm. In the emission spectrum of the emission light, absorption of light components above 740 nm is suppressed. On the other hand, by setting the bandgap wavelength λg4 to 740 nm or more, light components shorter than the bandgap wavelength λg4 are absorbed by the fourth layer 22b. Thus, external radiation intensity can be reduced. Also in this case, the refractive index n2 of the fourth layer 22b can be made higher than the refractive index n1 of the third layer 22a. Thus, the reflectance of the DBR layer 23 can be increased.

FIG. 3 is a graph showing the dependence of the bandgap wavelength on the Al composition ratio of AlₓGa₁₋ₓAs (0x≦x<0.45).

In the case where the Al composition ratio x is zero, the bandgap wavelength λgap is approximately 870 nm. With the increase of the Al composition ratio x, the bandgap wavelength λgap decreases. In the first embodiment, the range of the peak wavelength λp is set to 740 nm or more and 830 nm or less. Thus, in the case where the fourth layer 22b is made of AlₓGa₁₋ₓAs (0≦x≦1), the Al composition ratio x is set in the range of more than 0.056 and 0.2 or less. The bandgap wavelength λg3 of the third layer 22a and the bandgap wavelength λg4 of the fourth layer 22b are set equal to or less than the peak wavelength λp of the emission light. This suppresses absorption of the emission light from the light emitting layer 26 by the third layer 22a and the fourth layer 22b. Here, the refractive index is e.g. 3.61 for an Al composition ratio x of 0.03, and 3.47 for an Al composition ratio of 0.35.

Furthermore, in the first embodiment, for instance, the third layer 22a can be made of Al_{0.35}Ga_{0.65}As. Then, the bandgap wavelength λg3 can be set to approximately 680 nm, and the refractive index n1 can be set to approximately 3.47. The fourth layer 22b can be made of Al_{0.06}Ga_{0.94}As. Then, the bandgap wavelength λg4 can be set to approximately 827 nm, and the refractive index n2 can be set to approximately 3.63. That is, it is possible to use a combination of two direct-transition AlGaAs layers having different Al composition ratios x.

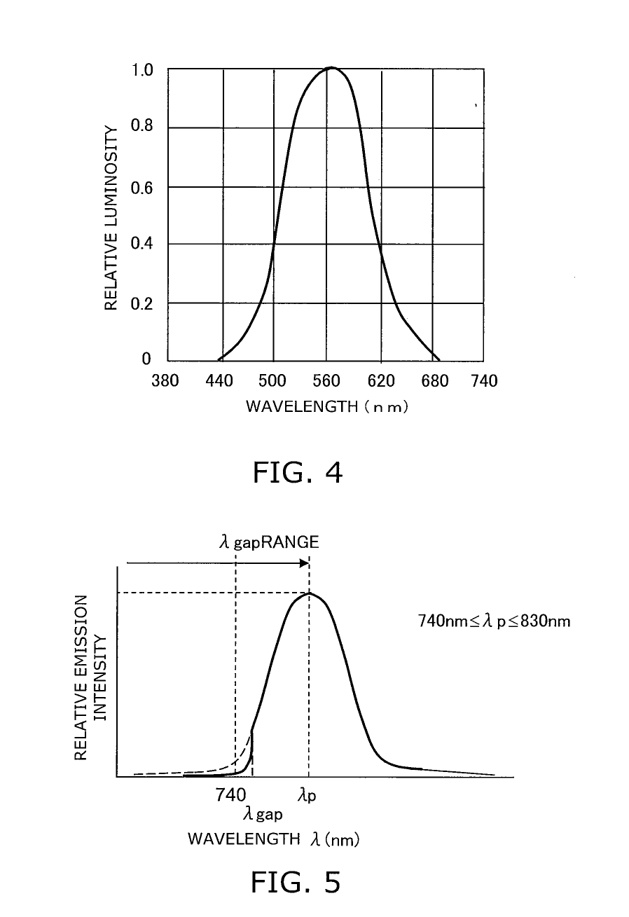

FIG. 4 is a graph showing luminosity curve.

The relative luminosity increases as the wavelength becomes shorter than 680 nm, and is maximized at the wavelength near 555 nm. The light including wavelength components of 680 nm or less having high relative luminosity is visible to the human eye even if its emission intensity is approximately one tenth of the emission intensity at the peak wavelength. That is, it is preferable to sufficiently reduce the emission intensity of visible light having a wavelength of 680 nm or less.

In the first embodiment, if the bandgap wavelength λgap of the fourth layer 22b is set to 740 nm or more, light components below the bandgap wavelength λgap can be absorbed.

FIG. 5 is a graph showing the range of the bandgap wavelength of the third layer and the fourth layer in the semiconductor light emitting device according to the first embodiment.

The bandgap wavelength λg3 of the third layer 22a and the bandgap wavelength λg4 of the fourth layer 22b are made shorter than the peak wavelength λp of the emission light. Here, the peak wavelength λp can be varied by the MQW structure of the light emitting layer 26.

Furthermore, the bandgap wavelength of the fourth layer 22b can be set to 740 nm or more. This facilitates absorbing light components with high relative luminosity to reduce leakage thereof to the outside of the semiconductor light emitting device 10. For instance, in the wavelength range below 740 nm, which is the lower bound of the peak wavelength λp, the emission intensity at wavelengths of approximately 680 nm or less having high relative luminosity can be sufficiently made lower than the emission intensity at the peak wavelength λp.

Furthermore, for instance, a layer 32d (FIG. 1A) is provided in the first layer 32. The bandgap wavelength λgap of the layer 32d is shorter than the peak wavelength λp minus 20 nm, and longer than the wavelength range having high relative luminosity (FIG. 4). Advantageously, this can further suppress external emission of visible light having high relative luminosity. The bandgap wavelength of the third layer 22a can be set to 740 nm or more.

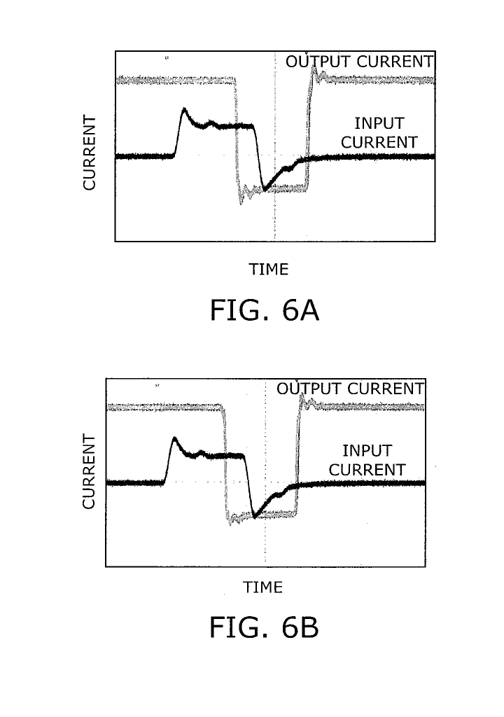

FIG. 6A is a graph showing the driving current waveform of the semiconductor light emitting device according to the first embodiment and the output current waveform converted from its emission light. FIG. 6B is a graph showing the driving current waveform of the semiconductor light emitting device according to the variation of the first embodiment and the output current waveform converted from its emission light.

The horizontal axis represents time, and the vertical axis represents the relative value of current. The semiconductor light emitting device is driven by an input current and emits an optical pulse. The optical pulse is received by e.g. a Si photodiode and converted to a current. Light emission by carrier recombination, and generation of carriers by optical excitation undergo a time delay as shown in FIGS. 6A and 6B.

In the semiconductor light emitting device according to the first embodiment, as shown in FIG. 2A, the emission intensity is sufficiently suppressed outside the wavelength range of 740-830 nm.

In the semiconductor light emitting device according to the variation of the first embodiment, as shown in FIG. 2B, the emission intensity is sufficiently suppressed outside the wavelength range of 740-830 nm. In both cases, noise components such as variations in the current waveform at the pulse fall time of photoelectric conversion are small. Hence, factors degrading signal transmission characteristics such as pulse width distortion and signal delay are small.

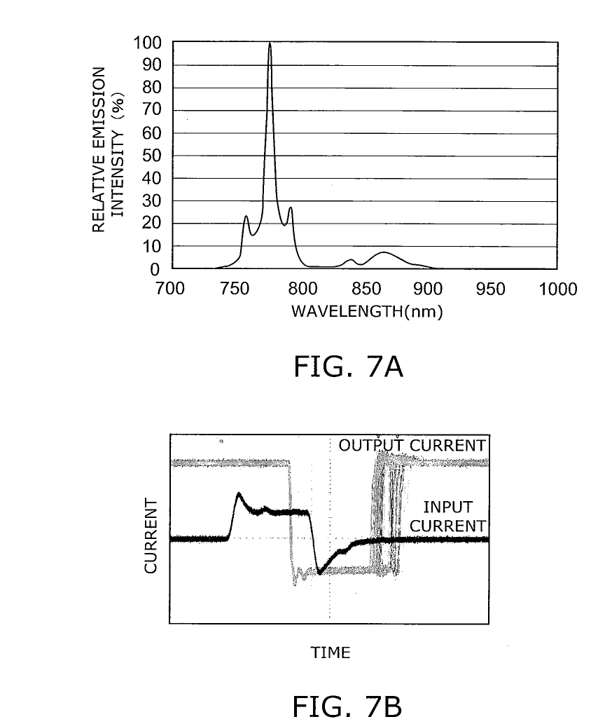

FIG. 7A is a graph showing the emission spectrum of a semiconductor light emitting device according to a comparative example. FIG. 7B shows an output current waveform by the light receiving device.

The DBR layer of the semiconductor light emitting device according to the comparative example includes GaAs. The bandgap wavelength of GaAs is generally 870 nm. Hence, GaAs is excited by absorbing the emission light of 740-830 nm and emits light at wavelengths near 870 nm. In addition, carriers overflowing the light emitting layer may recombine in GaAs and cause light emission at wavelengths near 870 nm.

As shown in FIG. 7A, these light components near 870 nm have a broad spectrum, although having emission intensity smaller than one tenth of the peak value. If emission light having a broad emission spectrum is converted to a current using a semiconductor light receiving device, then as shown in FIG. 7B, noise components such as variations in the current waveform at the fall time are made larger. This degrades signal transmission characteristics such as pulse width distortion and signal delay.

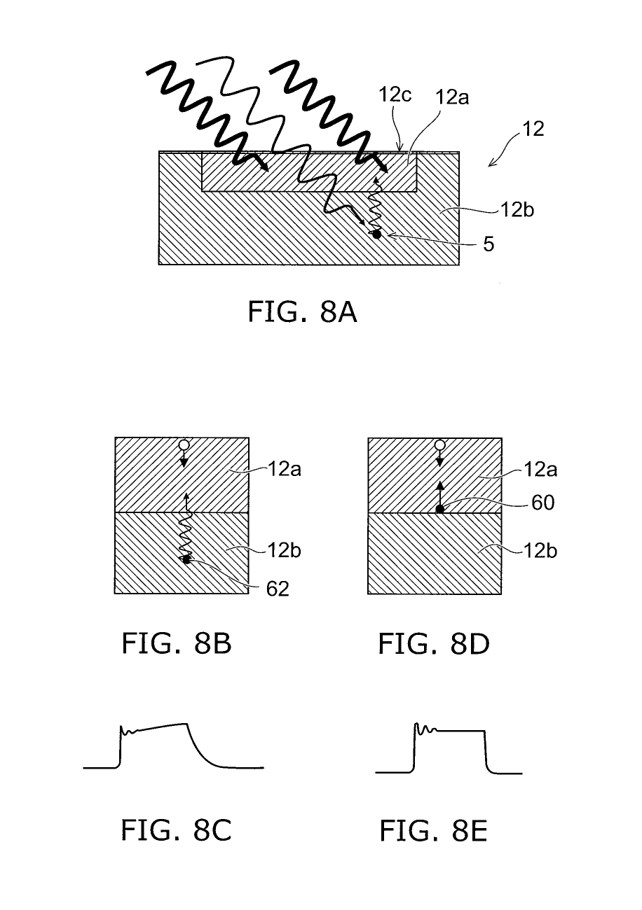

FIG. 8A is a schematic view describing diffusion carriers generated in the light receiving device. FIGS. 8B and 8C are schematic views describing the action by wavelength components longer than 830 nm. FIGS. 8D and 8E are schematic views describing the action by wavelength components of 830 nm or less.

The semiconductor light receiving device 12 is a Si photodiode, but is not limited thereto. In the incident light, long-wavelength light components reach into a deeper region from the surface than short-wavelength light components. Thus, light components with wavelengths longer than 830 nm are easily injected into the deep region 12b deeper than e.g. the depth of the depletion layer 12a.

A carrier 62 generated in the deep region 12b has a long transit time. This causes, as shown in FIG. 8C, the tailing phenomenon at the fall time of the output current waveform. Thus, carriers 62 generated in the deep region 12b deeper than the depletion layer 12a lead to a current waveform with a large variation in the fall time as shown in FIG. 7B. On the other hand, spectrum components with wavelengths shorter than 830 nm generate electron-hole pairs in the depletion layer 12a. Carriers 60 generated in the depletion layer 12a drift in opposite directions under reverse bias voltage and generate a current. In this case, because the transit time is short, the influence due to the tailing phenomenon can be reduced.

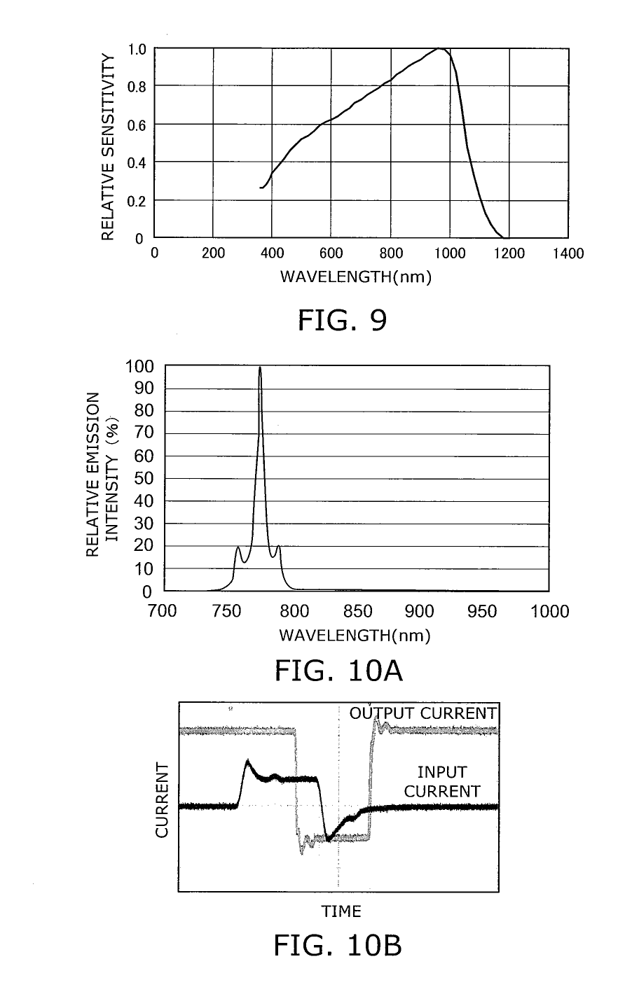

FIG. 9 is a graph showing the relative sensitivity of a Si photodiode.

The vertical axis represents relative sensitivity, and the horizontal axis represents wavelength (nm). The spectral sensitivity of the Si photodiode has a maximum near 960 nm. However, a shorter wavelength of incident light can suppress generation of carriers in the deep region. Thus, in the first embodiment, preferably, the peak wavelength of the semiconductor light emitting device is set to 830 nm or less. Although photodiodes made of Ge or InGaAs may also be used, the wavelength maximizing the spectral sensitivity is higher than that of Si. By combining the light emitting device of this embodiment with a Si photodiode, a remote control with high sensitivity and reduced malfunctions can be configured.

Next, a semiconductor light emitting device according to a second embodiment is described. In the second embodiment, the third layer 22a and the fourth layer 22b of the DBR layer 23 are made of indirect transition regions. As shown in FIG. 3, AlₓGa₁₋ₓAs (0≦x≦1) exhibits direct transition in the range of 0≦x<0.45, and indirect transition in the range of 0.45≦x≦1. For instance, the fourth layer 22b is made of Al_{0.5}Ga_{0.5}As and caused to exhibit indirect transition. The third layer 22a is made of an indirect transition region made of In_{0.5}Al_{0.5}P. In the indirect transition region, at the position with the momentum k being zero, the bottom of the conduction band is not matched with the top of the valence band. Hence, the probability of emission transition is made small. This suppresses light emission due to excitation by emission light in the wavelength range longer than the peak wavelength λp.

FIG. 10A is a graph of the emission spectrum of the semiconductor light emitting device according to the second embodiment. FIG. 10B is a graph showing the current waveform converted from its emission light.

As shown in FIG. 10A, the emission intensity outside the peak wavelength range is sufficiently suppressed. Furthermore, as shown in FIG. 10B, noise components such as variations in the current waveform at the pulse fall time of photoelectric conversion are small. Hence, factors degrading signal transmission characteristics such as pulse width distortion and signal delay are small.

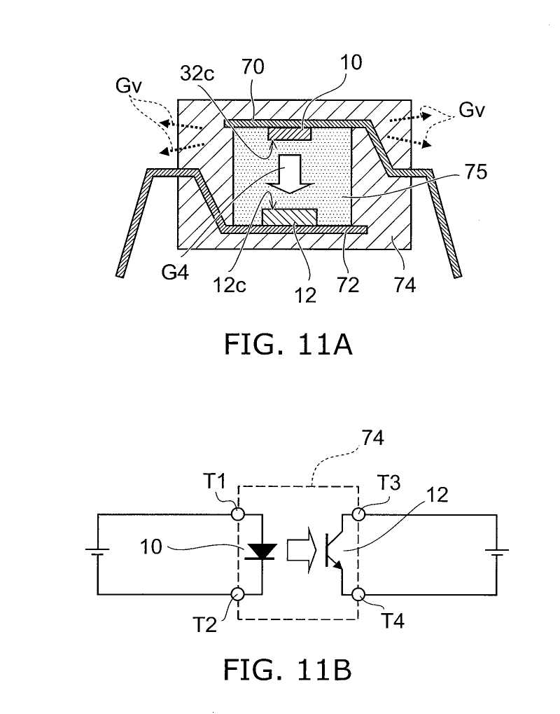

FIG. 11A is a schematic sectional view of a photocoupler according to this embodiment. FIG. 11B is a schematic view showing the connection of terminals.

As shown in FIG. 11A, the photocoupler includes the semiconductor light emitting device 10 according to this embodiment, a semiconductor light receiving device 12, an input lead 70, an output lead 72, and a support 74. The semiconductor light emitting device 10 is connected to the input lead 70. The semiconductor light receiving device 12 is connected to the output lead 72. The light extraction surface 32c of the semiconductor light emitting device 10 is opposed to the light receiving surface 12c of the semiconductor light receiving device 12.

The support 74 is made of e.g. resin, supports the input lead 70 and the output lead 72, and can internally house the semiconductor light emitting device 10 and the semiconductor light receiving device 12. A translucent resin layer 75 is provided in the optical path of emission light G4. The support 74 enclosing the translucent resin layer 75 can be made of a resin capable of blocking near infrared light. This can suppress unnecessary radiation of near infrared light to the outside, and suppress malfunctions due to near infrared light from the outside.

The semiconductor light emitting devices according to the first and second embodiment can sufficiently reduce emission intensity in the wavelength range above the peak wavelength. Thus, noise components such as variations in the current waveform at the pulse fall time of photoelectric conversion are reduced. This can suppress degradation of signal transmission characteristics such as pulse width distortion and signal delay.

The semiconductor light emitting device 10 according to this embodiment can easily reduce spectrum components below 740 nm. This can suppress leakage of visible light Gv having high relative luminosity to the outside of the support 74. Thus, the viewability of the optical coupler can be improved.

The semiconductor light emitting device 10 is bonded to the input lead 70. The input lead 70 includes a first terminal T1 and a second terminal T2. The first electrode of the semiconductor light emitting device 10 is connected to the first terminal T1. The second electrode of the semiconductor light emitting device 10 is connected to the second terminal T2. The semiconductor light receiving device 12 is bonded to the output lead 72. The output lead 72 includes a first terminal T3 and a second terminal T4. The first electrode of the light receiving device is connected to the first terminal T3. The second electrode of the light receiving device is connected to the second terminal T4. Thus, signal transmission can be performed with electrical insulation between the input lead 70 including the terminals T1 and T2 and the output lead 72 including the terminals T3 and T4. Such a photocoupler can be widely used in electronic equipment including industrial equipment, communication equipment, measuring equipment, and household electrical appliances.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor light emitting device comprising:
a light emitting layer having a first surface and a second surface provided on an opposite side of the first surface, the light emitting layer being capable of emitting emission light having a peak wavelength in a wavelength range of 740 nm or more and 830 nm or less;
a first layer of a first conductivity type provided on a side of the first surface of the light emitting layer and having a light extraction surface provided on an opposite side of the light emitting layer;
a second layer of a second conductivity type provided on a side of the second surface of the light emitting layer; and
a distributed Bragg reflector layer provided on a side of the second layer opposite to the light emitting layer and having the second conductivity type, a third layer and a fourth layer with a higher refractive index than the third layer being alternately stacked in the distributed Bragg reflector layer, and the distributed Bragg reflector layer being capable of reflecting the emission light toward the light extraction surface,
the third and fourth layers each having a bandgap wavelength shorter than the peak wavelength.

2. The device according to claim 1, wherein the third layer exhibits indirect transition.

3. The device according to claim 2, wherein the fourth layer exhibits indirect transition.

4. The device according to claim 1, wherein the bandgap wavelength of the fourth layer is 740 nm or more.

5. The device according to claim 1, wherein the first layer includes a layer having a bandgap wavelength shorter than the peak wavelength by 20 nm or more.

6. The device according to claim 1, wherein optical path length of one pair of the third layer and the fourth layer is half of in-medium wavelength of the emission light.

7. A semiconductor light emitting device comprising:
a light emitting layer having a first surface and a second surface provided on an opposite side of the first surface, the light emitting layer being capable of emitting emission light having a peak wavelength in a wavelength range of 740 nm or more and 830 nm or less, and the light emitting layer being made of one of AlₓGa₁₋ₓAs (0≦x<0.45) and InₓGa₁₋ₓAs (0≦x≦1);
a first layer of a first conductivity type provided on a side of the first surface of the light emitting layer and having a light extraction surface provided on opposite side from the light emitting layer;
a second layer of a second conductivity type provided on a side of the second surface of the light emitting layer; and
a distributed Bragg reflector layer provided on a side of the second layer opposite to the light emitting layer and having the second conductivity type, a third layer made of one of InₓAl₁₋ₓP (0≦x≦1) and Al_{y}Ga_{1-y}As (0≦y≦1) and a fourth layer made of Al_{z}Ga_{1-z}As (0≦z≦1) being alternately stacked in the distributed Bragg reflector layer, and the distributed Bragg reflector layer being capable of reflecting the emission light toward the light extraction surface,
the third and fourth layers each having a bandgap wavelength shorter than the peak wavelength.

8. The device according to claim 7, wherein the third layer exhibits indirect transition.

9. The device according to claim 8, wherein the third layer is Al_{y}Ga_{1-y}As, and Al composition ratio y is 0.45 or more and 1 or less.

10. The device according to claim 8, wherein the fourth layer exhibits indirect transition.

11. The device according to claim 10, wherein the fourth layer is Al_{z}Ga_{1-z}As, and Al composition ratio z is 0.45 or more and 1 or less.

12. The device according to claim 7, wherein
the third layer is Al_{y}Ga_{1-y}As (0≦y<0.45),
the fourth layer is Al_{z}Ga_{1-z}As (0≦z<0.45), and
Al composition ratio y and Al composition ratio z are different.

13. The device according to claim 7, wherein the bandgap wavelength of the fourth layer is 740 nm or more.

14. The device according to claim 7, wherein the first layer includes a layer having a bandgap wavelength shorter than the peak wavelength by 20 nm or more.

15. The device according to claim 7, wherein optical path length of one pair of the third layer and the fourth layer is half of in-medium wavelength of the emission light.

16. A photocoupler comprising:
a semiconductor light emitting device including:
a light emitting layer having a first surface and a second surface provided on an opposite side of the first surface, the light emitting layer being capable of emitting emission light having a peak wavelength in a wavelength range of 740 nm or more and 830 nm or less;
a first layer of a first conductivity type provided on a side of the first surface of the light emitting layer and having a light extraction surface provided on opposite side from the light emitting layer;
a second layer of a second conductivity type provided on a side of the second surface of the light emitting layer; and
a distributed Bragg reflector layer provided on a side of the second layer opposite to the light emitting layer and having the second conductivity type, a third layer and a fourth layer with a higher refractive index than the third layer being alternately stacked in the distributed Bragg reflector layer, and the distributed Bragg reflector layer being capable of reflecting the emission light toward the light extraction surface,
the third and fourth layers each having a bandgap wavelength shorter than the peak wavelength;
a semiconductor light receiving device capable of receiving the emission light from the semiconductor light emitting device and converting the emission light to an electrical signal;
an input lead connected to the semiconductor light emitting device;
an output lead connected to the light receiving device and electrically insulated from the input lead; and
a support supporting the input lead and the output lead and being capable of internally housing the semiconductor light emitting device and the semiconductor light receiving device.

17. The photocoupler according to claim 16, wherein the third layer exhibits indirect transition.

18. The photocoupler according to claim 17, wherein the fourth layer exhibits indirect transition.

19. The photocoupler according to claim 16, wherein the bandgap wavelength of the fourth layer is 740 nm or more.
